(19) United States
(12) Patent Application Publication
(10) Pub. No.: US 2025/0072074 A1
(43) Pub. Date: Feb. 27, 2025

(54) SUPERLATTICE COMPOSITE STRUCTURE AND SEMICONDUCTOR LAMINATE STRUCTURE

(71) Applicant: Wafer Works Corporation, Taoyuan City (TW)

(72) Inventors: Wen-Yu Lin, Taoyuan City (TW); Wei-Jen Hsueh, Taoyuan City (TW); Ping-Hai Chiao, Taoyuan City (TW)

(73) Assignee: Wafer Works Corporation, Taoyuan City (TW)

(21) Appl. No.: 18/522,150

(22) Filed: Nov. 28, 2023

(30) Foreign Application Priority Data
Aug. 24, 2023 (TW) 112131795

(51) Int. Cl. H01L 29/15; H01L 29/20; H01L 29/205; H01L 29/778

(52) U.S. Cl. CPC H01L 29/155; H01L 29/2003; H01L 29/205; H01L 29/7783

(57) ABSTRACT

A superlattice composite structure includes a first superlattice stack layer and a second superlattice stack layer. The first superlattice stack layer includes a plurality of first units stacked along a vertical direction. Each of the first units includes an aluminium nitride (AlN) layer, an aluminium gallium nitride (AlGaN) layer and a gallium nitride (GaN) layer stacked in sequence along the vertical direction. The second superlattice stack layer is stacked with the first superlattice stack layer along the vertical direction. The second superlattice stack layer includes a plurality of second units stacked along the vertical direction. Each of the second units includes another AlN layer, another AlGaN layer and another GaN layer stacked in sequence along the vertical direction.

### BACKGROUND OF THE INVENTION

### 1. Field of the Invention

The present disclosure relates to a superlattice composite structure and a semiconductor laminate structure, and more particularly, to a superlattice composite structure and a semiconductor laminate structure that are beneficial to release stress and reduce the degree or probability of the generation of crack lines on the surface thereof.

### 2. Description of the Prior Art

The GaN material has the characteristics of wide energy gap, high critical electric field, high thermal conductivity, high saturation electron velocity, high-frequency transmission capability, and small element size, such that the GaN material can be used as the main material of high-frequency transistor elements or high-voltage transistor elements, and is widely applied in many fields, such as solid-state lighting, display and 5G communication.

However, when the GaN epitaxy is grown on a heterogeneous substrate made of a material different from GaN (such as the heterogeneous substrates of sapphire, silicon carbide and silicon), high-density dislocations and large mismatch stress are existed in the GaN epitaxy due to the mismatches in lattice constants and thermal expansion coefficients between the GaN epitaxy and the heterogeneous substrate. As a result, problems of crystal defects, such as dislocations and cracks, and wafer warping are generated.

### SUMMARY OF THE INVENTION

According to one aspect of the present disclosure, a superlattice composite structure includes a first superlattice stack layer and a second superlattice stack layer. The first superlattice stack layer includes a plurality of first units stacked along a vertical direction. Each of the first units includes an aluminium nitride (AlN) layer, an aluminium gallium nitride (AlGaN) layer and a gallium nitride (GaN) layer stacked in sequence along the vertical direction. The second superlattice stack layer is stacked with the first superlattice stack layer along the vertical direction. The second superlattice stack layer includes a plurality of second units stacked along the vertical direction. Each of the second units includes another AlN layer, another AlGaN layer and another GaN layer stacked in sequence along the vertical direction. Each of the first units has a first unit thickness t1 along the vertical direction, each of the second units has a second unit thickness t2 along the vertical direction, and the following condition is satisfied: t1>t2.

According to another aspect of the present disclosure, a semiconductor laminate structure includes a substrate, a nucleation layer, the aforementioned superlattice composite structure, a channel layer, a polarized electron generation layer, a barrier layer and a cap layer. The nucleation layer is disposed on the substrate. The superlattice composite structure is disposed on the nucleation layer. The channel layer is disposed on the superlattice composite structure. The polarized electron generation layer is disposed on the channel layer. The barrier layer is disposed on the polarized electron generation layer. The cap layer is disposed on the barrier layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a superlattice composite structure according to an embodiment of the present disclosure.

FIG. 2 is a schematic cross-sectional view of a superlattice composite structure according to another embodiment of the present disclosure.

FIG. 3 is a schematic cross-sectional view of a semiconductor laminate structure according to an embodiment of the present disclosure.

FIG. 4 is a schematic cross-sectional view of a high electron mobility transistor (HEMT) according to an embodiment of the present disclosure.

FIG. 5 shows optical microscope (OM) images of semiconductor laminate structures of Comparative Examples 1, 2 and Example 1 according to the present disclosure.

FIG. 6 shows a scanning electron microscope (SEM) image of a portion of the semiconductor laminate structure of Example 1 according to the present disclosure.

FIG. 7 shows another SEM image of a portion of the semiconductor laminate structure of Example 1 according to the present disclosure.

FIG. 8 shows a transmission electron microscope (TEM) image of a portion of the semiconductor laminate structure of Example 1 according to the present disclosure.

FIG. 9 shows another TEM image of a portion of the semiconductor laminate structure of Example 1 according to the present disclosure.

FIG. 10 shows measurement results of electrical properties of HEMTs of Example 2 according to the present disclosure and Comparative Example 3.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, third, etc. may be used herein to describe various elements, parts, regions, layers and/or sections, these elements, parts, regions, layers and/or sections should not be limited by these terms. These terms may be only used to distinguish one element, part, region, layer and/or section from another element, part, region, layer and/or section. These terms do not imply or represent that there is any previous serial number prior the described element, nor represent the arrangement order of one element and another element or the order of the manufacturing method unless clearly indicated by the context. Thus, a first element, part, region, layer and/or section discussed below could be termed a second element, part, region, layer and/or section without departing from the teachings of the embodiments.

The numerical ranges and parameters described below are approximate values. Herein, “about” /“approximate” usually refers to the actual value within plus or minus 10%, 5%, 1% or 0.5% of a specific value or range. It should be understood that all ranges, quantities, values, proportions and percentages used herein are modified by the term “about”/“approximate”. Therefore, unless otherwise stated to the contrary, the values and parameters disclosed in the specification and the claims are approximate values and may be changed depending needs.

Furthermore, any two values or directions used for comparison may have a certain error. If a first value is equal to a second value, it implies that there may be an error of about 10% between the first value and the second value; if a first direction is perpendicular or “substantially” perpendicular to a second direction, then an angle between the first direction and the second direction may be between 80 degrees to 100 degrees; if the first direction is parallel or “substantially” parallel to the second direction, an angle between the first direction and the second direction may be between 0 degree to 10 degrees.

In the embodiments according to the present disclosure, a depth, a thickness, a width or a height of each element, or a space or a distance between elements may be measured by an optical microscope (OM), a scanning electron microscope (SEM), a transmission electron microscope (TEM) or other suitable methods. In some embodiments, a cross-sectional image of the element to be measured may be obtained by the SEM, and the depth, the thickness, the width or the height of each element, or the space or the distance between elements may be measured thereby.

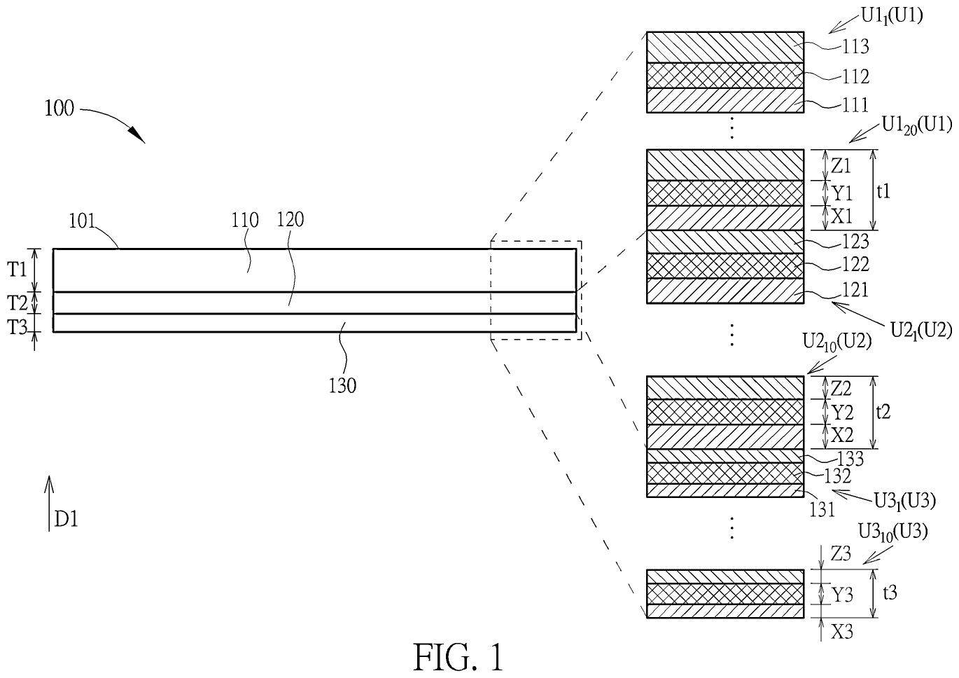

Please refer to FIG. 1, which is a schematic cross-sectional view of a superlattice composite structure 100 according to an embodiment of the present disclosure. The superlattice composite structure 100 includes a first superlattice stack layer 110 and a second superlattice stack layer 120. The first superlattice stack layer 110 includes a plurality of first units U1 stacked along a vertical direction D1. Each of the first units U1 includes an aluminium nitride (AlN) layer 111, an aluminium gallium nitride (AlGaN) layer 112 and a gallium nitride (GaN) layer 113 stacked in sequence along the vertical direction D1. The second superlattice stack layer 120 is stacked with the first superlattice stack layer 110 along the vertical direction D1. The second superlattice stack layer 120 includes a plurality of second units U2 stacked along the vertical direction D1. Each of the second units U2 includes an AlN layer 121, an AlGaN layer 122 and a GaN layer 123 stacked in sequence along the vertical direction D1. Each of the first units U1 has a first unit thickness t1 (wherein the “unit thickness” also called “superlattice (SL) pair thickness”) along the vertical direction D1, each of the second units U2 has a second unit thickness t2 along the vertical direction D1, and the following condition is satisfied: t1>t2. Thereby, the first unit thickness t1 of the first unit U1 and the second unit thickness t2 of the second unit U2 are configured to vary gradually along the vertical direction D1, which is beneficial to improve the ability for releasing stress.

The superlattice composite structure 100 may further include a third superlattice stack layer 130 stacked with the first superlattice stack layer 110 and the second superlattice stack layer 120 along the vertical direction D1. The third superlattice stack layer 130 includes a plurality of third units U3 stacked along the vertical direction D1, each of the third units U3 includes an AlN layer 131, an AlGaN layer 132 and a GaN layer 133 stacked in sequence along the vertical direction D1. Each of the third units U3 has a third unit thickness t3 along the vertical direction D1, and the following condition may be satisfied: t1>t2>t3. Thereby, the first unit thickness t1 of the first unit U1, the second unit thickness t2 of the second unit U2 and the third unit thickness t3 of the third unit U3 are configured to vary gradually along the vertical direction D1, which is beneficial to improve the ability for releasing stress.

In FIG. 1, the superlattice composite structure 100 includes three superlattice stack layers (i.e., the first superlattice stack layer 110, the second superlattice stack layer 120 and the third superlattice stack layer 130), which is exemplary and the present disclosure is not limited thereto. The number of the superlattice stack layers of the superlattice composite structure 100 may be adjusted according to actual needs. For example, the superlattice composite structure 100 may only include the first superlattice stack layer 110 and the second superlattice stack layer 120, or the superlattice composite structure 100 may further include a fourth superlattice stack layer (not shown), but not limited thereto.

In FIG. 1, the superlattice composite structure 100 has a top surface 101. The top surface 101 may define a normal direction (not shown). The aforementioned vertical direction D1 is parallel to the normal direction of the top surface 101.

The first unit U1 includes the AlN layer 111, the AlGaN layer 112 and the GaN layer 113 stacked in sequence from bottom to top along the vertical direction D1. The second unit U2 includes the AlN layer 121, the AlGaN layer 122 and the GaN layer 123 stacked in sequence from bottom to top along the vertical direction D1. The third unit U3 includes the AlN layer 131, the AlGaN layer 132 and the GaN layer 133 stacked in sequence from bottom to top along the vertical direction D1. However, the present disclosure is not limited thereto. In other embodiment, the GaN layer 113, the AlGaN layer 112 and the AlN layer 111 of the first unit U1, the GaN layer 123, the AlGaN layer 122 and the AlN layer 121 of the second unit U2, and the GaN layer 133, the AlGaN layer 132 and the AIN layer 131 of the third unit U3 may be stacked in sequence from bottom to top along the vertical direction D1.

The first unit U1 has the first unit thickness t1 along the vertical direction D1, the second unit U2 has the second unit thickness t2 along the vertical direction D1, the third unit U3 has the third unit thickness t3 along the vertical direction D1, and the following conditions may be satisfied: t1>100 Å; t2>100 Å; and t3>100 Å. Thereby, the configuration of the first unit thickness t1 of the first unit U1, the second unit thickness t2 of the second unit U2 and the third unit thickness t3 of the third unit U3 is beneficial to release stress. The aforementioned first unit thickness t1 may be the average value of the first unit thicknesses t1 of the plurality of first units U1 of the first superlattice stack layer 110, the aforementioned second unit thickness t2 may be average value of the second unit thicknesses t2 of the plurality of the second units U2 of the second superlattice stack layer 120, and the aforementioned third unit thickness t3 may be the average value of the third unit thicknesses t3 of the plurality of the third units U3 of the third superlattice stack layer 130.

The first superlattice stack layer 110 has a first thickness T1 along the vertical direction D1, the second superlattice stack layer 120 has a second thickness T2 along the vertical direction D1, the third superlattice stack layer 130 has a third thickness T3 along the vertical direction D1, and the following conditions may be satisfied: T1>T2; and T1>T3. That is, the first superlattice stack layer 110 may be configured as the main stack structure of the superlattice composite structure 100. Furthermore, the first thickness T1, the second thickness T2 and the third thickness T3 may satisfy the following conditions: T1>0.3 μm; T2>0.3 μm; T3>0.3 μm; and T1>T2>T3. Thereby, the first thickness T1 of the first superlattice stack layer 110, the second thickness T2 of the second superlattice stack layer 120 and the third thickness T3 of the third superlattice stack layer 130 are configured to vary gradually along the vertical direction D1, which is beneficial to improve the ability for releasing stress.

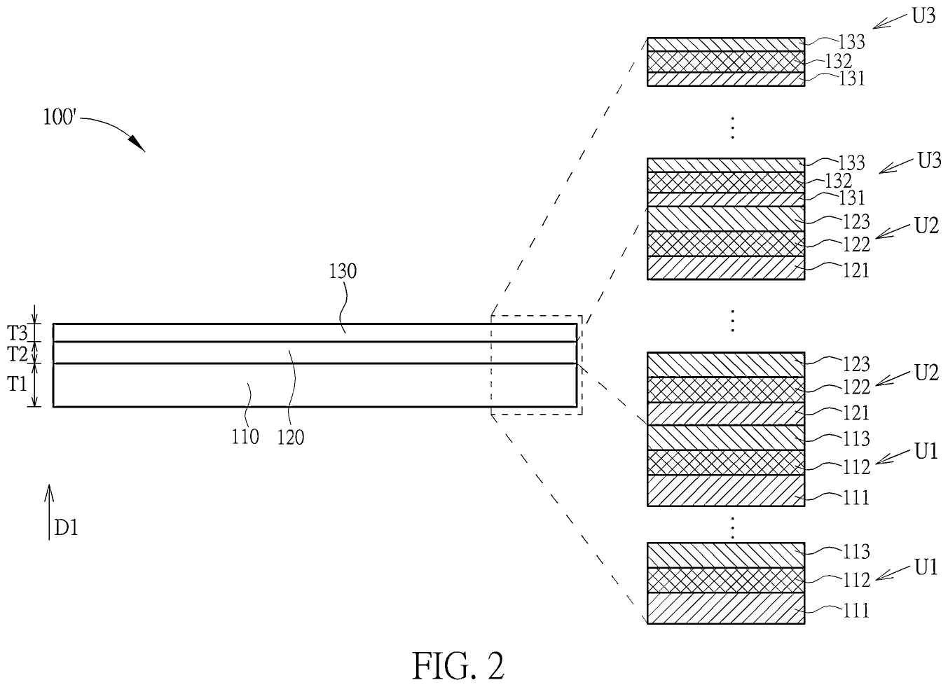

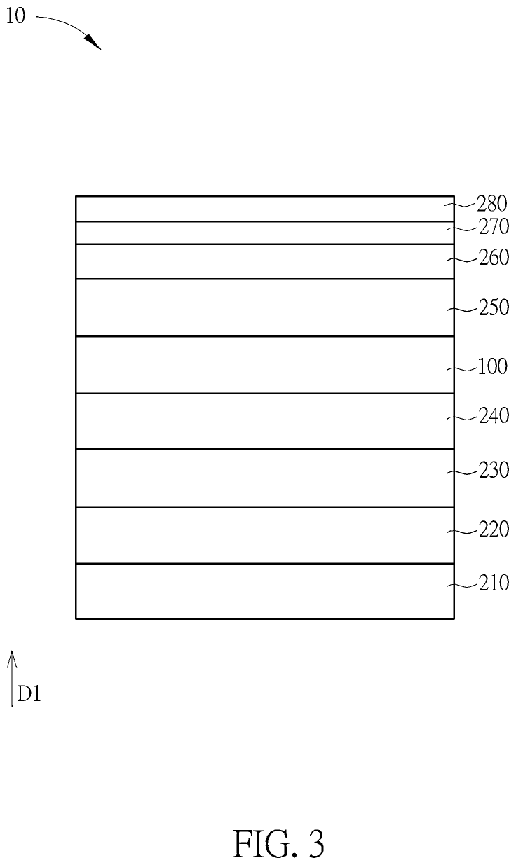

The superlattice composite structure 100 may be one of the layers of a semiconductor laminate structure (such as the semiconductor laminate structure 10 shown in FIG. 3). In FIG. 1, the third superlattice stack layer 130, the second superlattice stack layer 120 and the first superlattice stack layer 110 are stacked in sequence from bottom to top along vertical direction D1. However, the present disclosure is not limited thereto, and the stacking order of the third superlattice stack layer 130, the second superlattice stack layer 120 and the first superlattice stack layer 110 may be adjusted according to actual needs. Please refer to FIG. 2, which is a schematic cross-sectional view of a superlattice composite structure 100′ according to another embodiment of the present disclosure. The main difference between the superlattice composite structure 100′ and the superlattice composite structure 100 is that the first superlattice stack layer 110, the second superlattice stack layer 120 and the third superlattice stack layer 130 of the superlattice composite structure 100′ are stacked in sequence from bottom to top along the vertical direction D1. In other words, the first unit thickness t1 of the first unit U1, the second unit thickness t2 of the second unit U2 and the third unit thickness t3 of the third unit U3 are configured to decrease gradually from top to bottom along the vertical direction D1 (as shown in FIG. 1) or decrease gradually from bottom to top along the vertical direction D1 (as shown in FIG. 2); the first thickness T1 of the first superlattice stack layer 110, the second thickness T2 of the second superlattice stack layer 120 and the third thickness T3 of the third superlattice stack layer 130 are configured to decrease gradually from top to bottom along the vertical direction D1 (as shown in FIG. 1) or decrease gradually from bottom to top along the vertical direction D1 (as shown in FIG. 2), all of which are fallen within the scope of the present disclosure.

Please refer back to FIG. 1. The AlN layer 111 of the first unit U1 has a first sub-thickness X1 along the vertical direction D1, the AlGaN layer 112 of the first unit U1 has a second sub-thickness Y1 along the vertical direction D1, the GaN layer 113 of the first unit U1 has a third sub-thickness Z1 along the vertical direction D1, the AlN layer 121 of the second unit U2 has a fourth sub-thickness X2 along the vertical direction D1, the AlGaN layer 122 of the second unit U2 has a fifth sub-thickness Y2 along the vertical direction D1, the GaN layer 123 of the second unit U2 has a sixth sub-thickness Z2 along the vertical direction D1, the AlN layer 131 of the third unit U3 has a seventh sub-thickness X3 along the vertical direction D1, the AlGaN layer 132 of the third unit U3 has an eighth sub-thickness Y3 along the vertical direction D1, the GaN layer 133 of the third unit U3 has a ninth sub-thickness Z3 along the vertical direction D1, and the following conditions may be satisfied: Y1<X1<Z1; Y2<X2<Z2; and Y3<X3<Z3. Thereby, in the first unit U1, the AlGaN layer 112 has the thinnest thickness; in the second unit U2, the AlGaN layer 122 has the thinnest thickness; in the third unit U3, the AlGaN layer 132 has the thinnest thickness. With further incorporating the AlN layers having different thicknesses, it is beneficial to improve the ability for releasing stress.

When the third superlattice stack layer 130, the second superlattice stack layer 120 and the first superlattice stack layer 110 are stacked in sequence from bottom to top along the vertical direction D1, the composition of the AlGaN layer 112 of the first unit U1 is A1₍₁₋ᵢ₎GaᵢN, the composition of the AlGaN layer 122 of the second unit U2 is Al₍₁₋ⱼ₎GaⱼN, the composition of the AlGaN layer 132 of the third unit U3 is Al₍₁₋ₖ₎GaₖN, each of i, j and k is a constant greater than zero and less than 1, and the following condition may be satisfied: i>j>k. Thereby, the contents of gallium from the AlGaN layer 112 of the first unit U1 to the AlGaN layer 132 of the third unit U3 are configured to decrease gradually from top to bottom along the vertical direction D1, and the contents of aluminum from the AlGaN layer 112 of the first unit U1 to the AlGaN layer 132 of the third unit U3 are configured to increase gradually from top to bottom along the vertical direction D1, which are beneficial to reduce the generation of crack lines.

The AlN layer 111 of the first unit U1 has the first sub-thickness X1 along the vertical direction D1, the AlGaN layer 112 of the first unit U1 has the second sub-thickness Y1 along the vertical direction D1, the GaN layer 113 of the first unit U1 has the third sub-thickness Z1 along the vertical direction D1, and the second sub-thickness Y1 may be between the first sub-thickness X1 and the third sub-thickness Z1. That is, the following condition may be satisfied: X1>Y1>Z1; or Z1>Y1>X1. Thereby, the ability for withstanding stress may be improved. Similarly, in the second unit U2, the fifth sub-thickness Y2 may be between the fourth sub-thickness X2 and the sixth sub-thickness Z2. That is, the following condition may be satisfied: X2>Y2>Z2; or Z2>Y2>X2; in the third unit U3, the eighth sub-thickness Y3 may be between the seventh sub-thickness X3 and the ninth sub-thickness Z3. That is, the following condition may be satisfied: X3>Y3>Z3; or Z3>Y3>X3.

In FIG. 1, the number of the first units U1 is m (or may be called m pairs). In order to distinguish the plurality of the first units U1, the plurality of the first units U1 may be further named as U1ₐ, and a is an integer from 1 to m. The number of the second units U2 is n (or may be called n pairs). In order to distinguish the plurality of the second units U2, the plurality of the second units U2 may be further named as U2b, and b is an integer from 1 to n. The number of the third units U3 is o (or may be called o pairs). In order to distinguish the plurality of the third units U3, the plurality of the third units U3 may be further named as U3_{c}, and c is an integer from 1 to o. In the embodiment, the number of the first units U1 is 20 (i.e., m=20), the number of the second units U2 is 10 (i.e., n=10), and the number of the third units U3 is 10 (i.e., o=10), which are exemplary. For the sake of simplicity, only the first unit U1₁ at top most, the first unit U1₂₀ at bottom most, the second unit U2₁ at top most, the second unit U2₁₀ at bottom most, the third unit U3₁ at top most and the third unit U3₁₀ at bottom most are illustrated. However, the present disclosure is not limited thereto, and the numbers of the first units U1, the second units U2 and the third units U3 may be adjusted according to actual needs.

The number of the first units U1 is m, the composition of the AlGaN layer 112 of each of the first units U1 is Al₍₁₋ᵢₐ₎GaᵢₐN, a is an integer from 1 to m, ia is a constant greater than zero and less than 1, in which i1 (i.e., a=1 in ia) to im (i.e., a=m in ia) may be configured to decrease gradually from top to bottom along the vertical direction D1, while 1-ia to 1-im may be configured to increase gradually from top to bottom along the vertical direction D1. That is, the contents of gallium of the AlGaN layers 112 of the plurality of the first units U1 may decrease gradually from top to bottom along the vertical direction D1 (i1>im), while the contents of aluminum of the AlGaN layers 112 of the plurality of the first units U1 may increase gradually from top to bottom along the vertical direction D1 correspondingly. For a more specific example, when the number of the first units U1 is 20 (i.e., m=20), the plurality of the first units U1, from top to bottom, are the first unit U1₁, U1₂, . . . , U1₁₉ and U1₂₀. The composition of the AlGaN layer 112 of the first unit U1₁ is Al₍₁₋ᵢ₁₎Gaᵢ₁N, the composition of the AlGaN layer 112 of the first unit U1₂ is Al₍₁₋ᵢ₂₎Gaᵢ₂N, the composition of the AlGaN layer 112 of the first unit U1₁₉ is Al₍₁₋ᵢ₁₉₎Gaᵢ₁₉N, and the composition of the AlGaN layer 112 of the first unit U1₂₀ is Al₍₁₋ᵢ₂₀₎Gaᵢ₂₀N, in which i1 to i20 are configured to decrease gradually from top to bottom along the vertical direction D1. That is, the contents of gallium of the AlGaN layers 112 from the first unit U1₁ to the first unit U1₂₀ are configured to decrease gradually from top to bottom along vertical direction D1(i1>i20), and the contents of aluminum of the AlGaN layers 112 from the first unit U1₁ to the first unit U1₂₀ are configured to increase gradually from top to bottom along the vertical direction D1. The lattice constant of aluminum is smaller. By placing the aluminum with smaller lattice constant below is beneficial to ease the tensile stress, so that the generation of the crack lines can be reduced.

Similarly, the number of the second units U2 is n, the composition of the AlGaN layer 122 of each of the second units U2 is Al_{(1-jb)}Ga_{jb}N, b is an integer from 1 to n, jb is a constant greater than zero and less than 1, in which j1 (i.e., b=1 in jb) to jn (i.e., b=n in jb) may be configured to decrease gradually from top to bottom along the vertical direction D1. The number of the third units U3 is o, the composition of the AlGaN layer 132 of each of the third units U3 is Al_{(1-kc)}Ga_{kc}N, c is an integer from 1 to o, kc is a constant greater than zero and less than 1, in which k1 (i.e., c=1 in kc) to ko (i.e., c=o in kc) may be configured to decrease gradually from top to bottom along the vertical direction D1. When i1 to im of the plurality of the first units U1 are configured to decrease gradually from top to bottom along the vertical direction D1, j1 to jn of the plurality of the second units U2 and k1 to ko of the plurality of the third units U3 are also configured to decrease gradually from top to bottom along the vertical direction D1. Thereby, it is beneficial to improve the ability for releasing stress.

The superlattice composite structure 100 may be one of the layers 41 semiconductor laminate structure (such as the semiconductor laminate structure 10 in FIG. 3). The materials of the layers disposed above and below the superlattice composite structure 100 are different. When the materials are different, it is easy to generate crystal dislocations and stress due to factors such as the mismatches in lattice constants and thermal expansion coefficients between different materials, resulting in crystal defects. With the superlattice composite structure 100 has a periodic and varying gradually stack structure, it is beneficial to improve the ability to release stress and reduce the degree or probability of the generation of crack lines on the surface.

Please refer to FIG. 3, which is a schematic cross-sectional view of a semiconductor laminate structure 10 according to an embodiment of the present disclosure. The semiconductor laminate structure 10 includes, from bottom to top, a substrate 210, a nucleation layer 220, the superlattice composite structure 100, a channel layer 250, a polarized electron generation layer 260, a barrier layer 27 and a cap layer 280. The semiconductor laminate structure 10 may optionally include a first buffer layer 230 and a second buffer layer 240.

The substrate 210 may be made of silicon or other semiconductor materials or may be a composite substrate. In one embodiment, the substrate 210 is, for example, a silicon layer with a <111> lattice structure, but not limited thereto; in other embodiment, the substrate 210 may also have a semiconductor compound, such as silicon carbide (SiC), gallium arsenide (GaAs), indium arsenide (InAs) or indium phosphide (InP), or may have a semiconductor alloy, such as silicon germanium (SiGe), silicon germanium carbide (SiGeC), gallium arsenide phosphide (AsGaP), or indium gallium phosphide (InGaP). The thickness of the substrate 210 may be 100 μm to 2000 μm.

The nucleation layer 220 is disposed on the substrate 210. The material of the nucleation layer 220 may be AlN or Inₓ₁Al_{y1}Ga_{1-x1-y1}N, and the following conditions may be satisfied: 0≤x1≤1; 0≤y1≤1; and x1+y1≤1. Alternatively, the following conditions may be satisfied: 0≤x1<0.01; and 0.9<y1≤1. When forming the nucleation layer 220, the process temperature may be increased gradually. For example, the process temperature may be increased 10° C. to 15° C. per minute. The thickness of the nucleation layer 220 may be 1 nm to 500 nm. Thereby, the bonding between the substrate 210 and other layers can be improved, and the probability of the generation of cracks and warping can be reduced.

The first buffer layer 230 is disposed on the nucleation layer 220 and is configured to buffer the stress from the substrate 210. The material of the first buffer layer 230 may be AlGaN. The thickness of the first buffer layer 230 may be greater than 0 nm and less than or equal to 2000 nm. In addition, the first buffer layer 230 may also be a superlattice structure composed of multiple semiconductor layers.

The second buffer layer 240 is disposed on the first buffer layer 230, and is configured to buffer the stress from the substrate 210. The material of the second buffer layer 240 may be AlGaN. The thickness of the second buffer layer 240 may be greater than 0 nm and less than or equal to 2000 nm. In addition, the second buffer layer 240 may also be a superlattice structure composed of multiple semiconductor layers. In the embodiment, the semiconductor laminate structure 10 includes two buffer layers (i.e., the first buffer layer 230 and the second buffer layer 240), which is exemplary, and the present disclosure is not limited thereto. The buffer layer may be omitted or the number of buffer layers may be adjusted according to actual needs.

The superlattice composite structure 100 is disposed on the nucleation layer 220. Herein, the superlattice composite structure 100t is indirectly disposed on the nucleation layer 220 through the first buffer layer 230 and the second buffer layer 240. For details of the superlattice composite structure 100, reference may be made to the above description, and are omitted herein. In other embodiments, the superlattice composite structure 100 may be replaced by the superlattice composite structure 100′ shown in FIG. 2. The thickness of the superlattice composite structure 100 may be 0.5 μm to 20 μm.

The channel layer 250 is disposed on the superlattice composite structure 100. The material of the channel layer 250 may be GaN. The thickness of the channel layer 250 may be 50 nm to 5000 nm.

The polarized electron generation layer 260 is disposed on the channel layer 250. The material of the polarized electron generation layer 260 may be AlN. The thickness of the polarized electron generation layer 260 may be 0.5 nm to 10 nm.

The barrier layer 270 is disposed on the polarized electron generation layer 260. The material of the barrier layer 270 may be AlInGaN. The thickness of the barrier layer 270 may be 1 nm to 50 nm.

The cap layer 280 is disposed on the barrier layer 270. The material of the cap layer 280 may be P-type GaN or P-type Alₓ₈Ga₁₋ₓ₈N, and the following condition may be satisfied: 0<x8<1. The thickness of the cap layer 280 may be 0.5 nm to 50 nm.

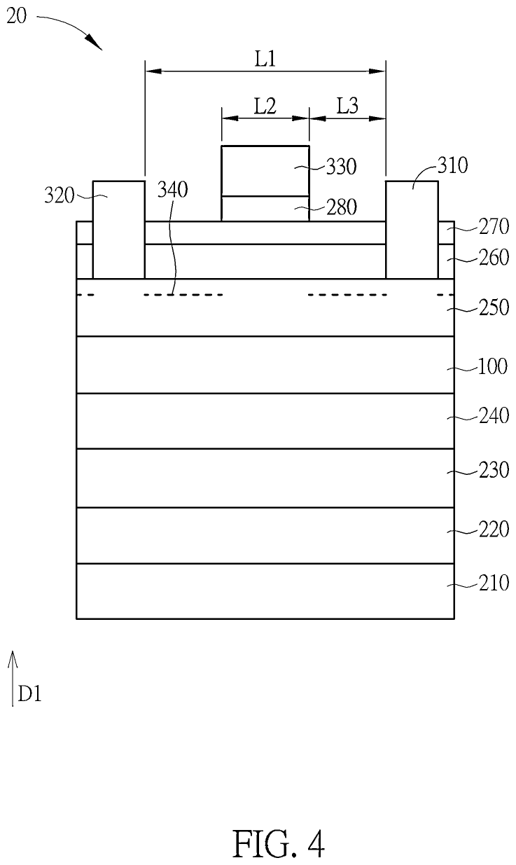

The nucleation layer 220, the first buffer layer 230, the second buffer layer 240, the superlattice composite structure 100, the channel layer 250, the polarized electron generation layer 260, the barrier layer 270 and the cap layer 280 of the semiconductor laminate structure 10 may all be formed by epitaxial growth through the metal-organic chemical vapor deposition (MOCVD), and the thickness of each layer may be adjusted through process parameters, such as pressure, temperature and time. The semiconductor laminate structure 10 may be further processed to form a desired semiconductor element or device, such as the HEMT 20 shown in FIG. 4.

Please refer to FIG. 4, which is a schematic cross-sectional view of a HEMT 20 according to an embodiment of the present disclosure. The HEMT 20 may be obtained by processing the semiconductor laminate structure 10. Specifically, the HEMT 20 further includes a gate electrode 330, a source electrode 310 and a drain electrode 320 compared with the semiconductor laminate structure 10. The gate electrode 330 is disposed on the cap layer 280, and the source electrode 310 and the drain electrode 320 are respectively disposed at two sides of the gate electrode 330 and located above the channel layer 250. The source electrode 310 and the drain electrode 320 may penetrate through the polarized electron generation layer 260 to reach the top surface of the channel layer 250, or reach into the channel layer 250 by a depth (not shown). As shown in FIG. 4, the region not covered by the cap layer 280 may form a two-dimensional electron gas (2DEG) 340 due to the piezoelectric effect generated between the channel layer 250 and the polarized electron generation layer 260. With the gate electrode 330 applying a bias voltage to the P-type cap layer 280, the concentration of the 2DEG 340 in the channel layer 250 located below the P-type cap layer 280 can be controlled. Thereby, the ON/OFF state of the HEMT 20 can be controlled. Compared with silicon power transistors, the HEMT 20 has a wider energy band gap. Accordingly, the HEMT 20 has the characteristics of low on-state resistance (RON) and low switching loss. The HEMT 20 can be used as a power switching transistor for voltage converter applications or can be applied to the high-power telecommunication applications, but the present disclosure is not limited thereto. How to form the gate electrode 330, the source electrode 310 and the drain electrode 320 on the semiconductor laminate structure 10 is well known in the art and is omitted herein.

### EXAMPLES AND COMPARATIVE EXAMPLES

First, the semiconductor laminate structures of Example 1 and Comparative Examples 1 and 2 are provided. The semiconductor laminate structure of Example 1 includes, from bottom to top, a substrate, a nucleation layer, a first buffer layer, a second buffer layer, a superlattice composite structure, a channel layer, a polarized electron generation layer, a barrier layer and a cap layer, in which the superlattice composite structure includes a first superlattice stack layer, a second superlattice stack layer and a third superlattice stack layer. The first superlattice stack layer includes 20 pairs of the first units stacked along the vertical direction, the second superlattice stack layer includes 10 pairs of the second units stacked along the vertical direction, and the third superlattice stack layer includes 10 pairs of the third units stacked along the vertical direction. Each of the first units, the second units and the third units includes an AlN layer, an AlGaN layer and a GaN layer stacked in sequence along the vertical direction. The configuration of each layer of the superlattice composite structure of Example 1 may refer to that of the superlattice composite structure 100 shown in FIG. 1. The materials and thicknesses of the layers of the semiconductor laminate structure may refer to Table 1. The difference between Comparative Example 1 and Example 1 is that the superlattice composite structure of Comparative Example 1 only includes 40 pairs of the first units. The difference between Comparative Example 2 and Example 1 is that the superlattice composite structure of Comparative Example 2 only includes 40 pairs of the third units.

TABLE 1

| | Material | Thickness |
|---|---|---|
| Cap layer | GaN | 0.5 nm-50 nm |
| Barrier layer | AlInGaN | 1 nm-50 nm |
| Polarized electron | AlN | 0.5 nm-10 nm |
| generation layer | | |
| Channel layer | GaN | 50 nm-5000 nm |
| Superlattice | AlN/Al₍₁₋ᵢ₎GaᵢN/GaN// | 0.5 μm-20 μm |
| composite structure | AlN/Al₍₁₋ⱼ₎GaⱼN/GaN// | |
| | AlN/Al₍₁₋ₖ₎GaₖN/GaN | |
| Second buffer layer | AlGaN | 0-2000 nm |
| First buffer layer | AlGaN | 0-2000 nm |
| Nucleation layer | AlN | 1 nm-500 nm |
| Substrate | Si | 100 μm-2000 μm |

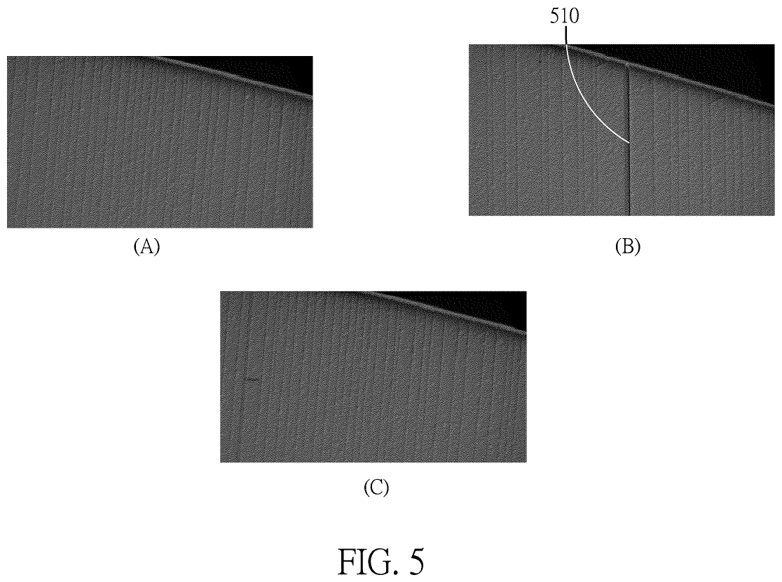

An OM is used to observe the surface morphologies of the semiconductor laminate structures of Example 1 and Comparative Examples 1 and 2, and an X-ray diffractometer (XRD) is used to perform the X-ray diffraction analysis. The results are shown in FIG. 5 and Table 2.

Please refer to FIG. 5, which shows OM images of the semiconductor laminate structures of Comparative Examples 1, 2 and Example 1 according to the present disclosure, in which the portion A is the OM image of the cap layer of the semiconductor laminate structure of Comparative Example 1, the portion B is the OM image of the cap layer of the semiconductor laminate structure of Comparative Example 2, and the portion C is the OM image of the cap layer of the semiconductor laminate structure of Example 1. As shown in FIG. 5, an obvious crack line 510 can be observed in the cap layer of the semiconductor laminate structure of Comparative Example 2.

Please refer to Table 2, which shows measurement results of the XRD of the semiconductor laminate structures of Comparative Examples 1 and 2 and Example 1 according to the present disclosure. Specifically, the full widths at half maximum (FWHM) of the crystal faces <002> and <102> of the cap layers of the semiconductor laminate structures are shown. As shown in Table 2, the FWHM of the crystal face <102> of Comparative Example 1 is significantly higher than that of Comparative Example 2 and Example 1, which represents that the cap layer of the semiconductor laminate structure of Comparative Example 1 has more crystal defects. As shown in FIG. 5 and Table 2, compared with Comparative Example 2 having the obvious crack line 510 and Comparative Example 1 having a higher FWHM, the superlattice composite structure of Example 1 according to the present disclosure can effectively improve the quality of epitaxy. For example, the FWHM of the cap layer (herein, GaN epitaxy) may be reduce, and the generation of the crack line on surface may be reduce.

TABLE 2

| | FWHM of crystal face | FWHM of crystal face |
|---|---|---|
| | <002> (arcsec) | <102> (arcsec) |
| Comparative example 1 | 477 | 903 |
| Comparative example 2 | 456 | 723 |
| Example 1 | 467 | 695 |

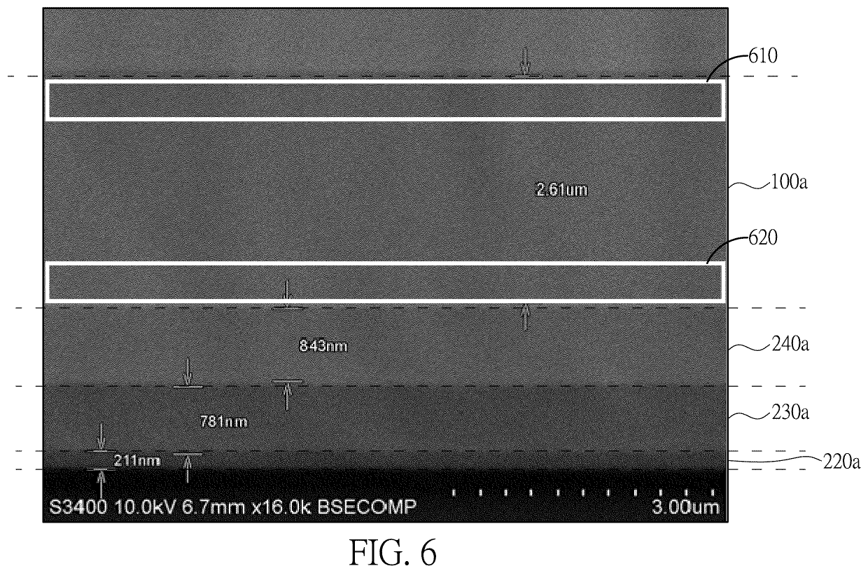

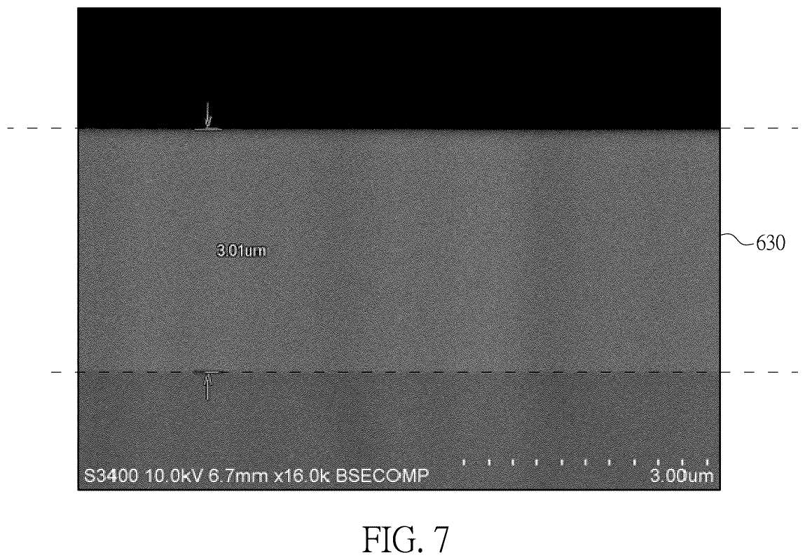

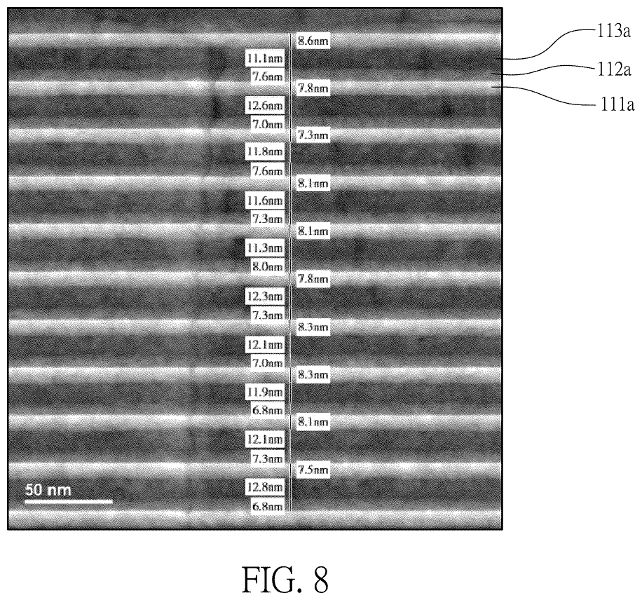

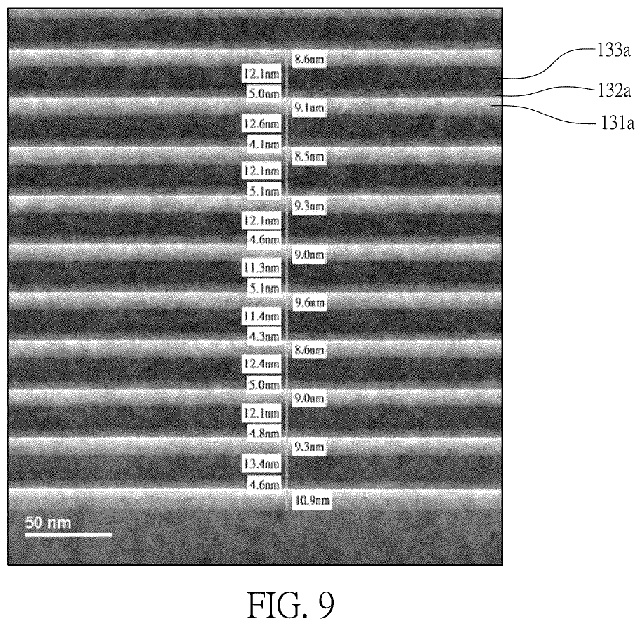

Please refer to FIG. 6, FIG. 7, FIG. 8 and FIG. 9. FIG. 6 shows a SEM image of a portion of the semiconductor laminate structure of Example 1 according to the present disclosure. FIG. 7 shows another SEM image of a portion of the semiconductor laminate structure of Example 1 according to the present disclosure. FIG. 8 shows a TEM image of a portion of the semiconductor laminate structure of Example 1 according to the present disclosure. FIG. 9 shows another TEM image of a portion of the semiconductor laminate structure of Example 1 according to the present disclosure, in which FIG. 8 is corresponding to the portion 610 shown in FIG. 6, and FIG. 9 is corresponding to the portion 620 shown in FIG. 6. In FIG. 6, there are, from bottom to top, the nucleation layer 220a, the first buffer layer 230a, the second buffer layer 240a and the superlattice composite structure 100a. The thickness of the nucleation layer 220a is 211 nm, the thickness of the first buffer layer 230a is 781 nm, the thickness of the second buffer layer 240a is 843 nm, and the thickness of the superlattice composite structure 100a is 2.61 μm. The portion 610 is corresponding to a portion of the first superlattice stack layer (not labeled) of the superlattice composite structure 100a, and the portion 620 is corresponding to a portion of the third superlattice stack layer (not labeled) of the superlattice composite structure 100a. In FIG. 7, the portion 630 is corresponding to the range of the channel layer, the polarized electron generation layer, the barrier layer and the cap layer. That is, the thickness of the channel layer, the polarized electron generation layer, the barrier layer and the cap layer is 3.01 μm. As shown in FIG. 6 to FIG. 7, the total thickness of the semiconductor laminate structure is approximately 7.46 μm. In other words, in Example 1, a nitride epitaxial layer with a thickness of 7.46 μm can be successfully grown on the silicon substrate, which shows that the superlattice composite structure 100a can effectively release stress. In FIG. 8, at least 10 pairs of the first units are shown. Each pair of the first unit includes an AlN layer 111a, an AlGaN layer 112a and a GaN layer 113a stacked in sequence from bottom to top. In each pair of the first unit, the thickness of the AlGaN layer 112a (i.e., the second sub-thickness Y1) is less than the thickness of the AlN layer 111a (i.e., the first sub-thickness X1), and the thickness of the AlN layer 111a (i.e., the first sub-thickness X1) is less than the thickness of the GaN layer 113a (i.e., the third sub-thickness Z1). That is, the following condition is satisfied: Y1<X1<Z1. In FIG. 9, at least 10 pairs of the third units are shown. Each pair of the third unit includes an AlN layer 131a, an AlGaN layer 132a and a GaN layer 133a stacked in sequence from bottom to top. In each pair of the third unit, the thickness of the AlGaN layer 132a (i.e., the eighth sub-thickness Y3) is less than the thickness of the AlN layer 131a (i.e. the seventh sub-thickness X3), and the thickness of the AIN layer 131a (i.e. the seventh sub-thickness X3) is less than the thickness of the GaN layer 133a (i.e. the ninth sub-thickness Z3). That is, the following condition is satisfied: Y3<X3<23. In addition, as shown in FIG. 8 and FIG. 9, the first unit thickness t1 and the third unit thickness t3 satisfy the following condition: t1>t3.

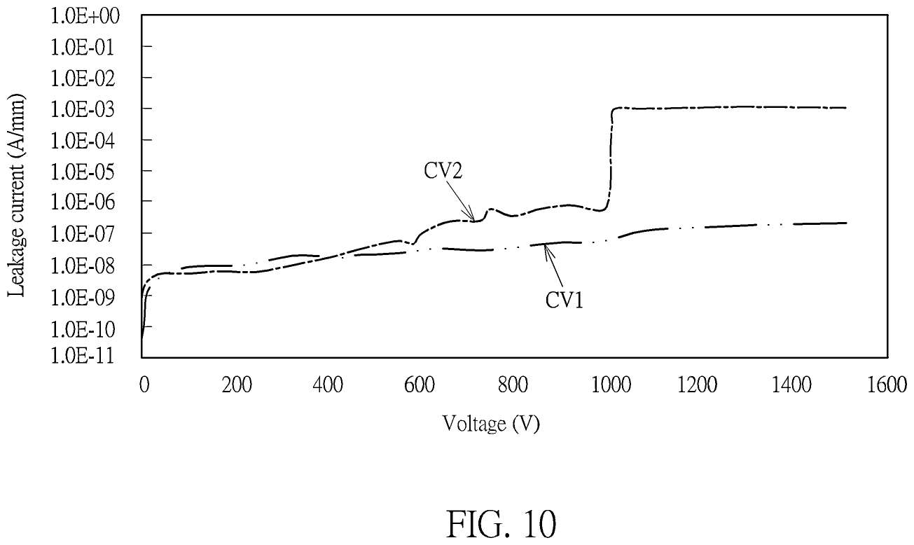

Please refer to FIG. 10, which shows measurement results of the electrical properties of the HEMTs of Example 2 according to the present disclosure and Comparative Example 3. The HEMT of Example 2 is obtained by further forming a source electrode, a drain electrode and a gate electrode on the semiconductor laminate structure of Example 1. The parameters of the HEMT of Example 2 are shown in Table 3, in which the length from the source electrode to the drain electrode may refer to the length L1 shown in FIG. 4, the gate electrode length may refer to the length L2 shown in FIG. 4, and the length from the gate electrode to the source electrode may refer to length L3 shown in FIG. 4.

TABLE 3

| | |
|---|---|
| The length from the source electrode to the drain | 25 |
| electrode (μm) | |
| The gate electrode length (μm) | 2 |
| The length from the gate electrode to the source | 20 |
| electrode (μm) | |

In FIG. 10, the curve CV1 is the measurement result of the electrical property of the HEMT of Example 2 according to the present disclosure, and the curve CV2 is the measurement result of the electrical property of the HEMT of Comparative Example 3. The main difference between Comparative Example 3 and Example 2 is that the superlattice composite structure of Comparative Example 3 only includes a single superlattice stack layer, and the single superlattice stack layer includes a plurality of AlN/AlGaN/GaN units stacked along the vertical direction. In FIG. 10, the data is obtained when the gate voltage is −24 V and the 2DEG is in the off state. As shown in the curve CV2, the leakage current of the HEMT of Comparative Example 3 increases more rapidly as the voltage increases, and a hard break occurs when the voltage is 1010V. As shown in the curve CV1, the HEMT of Example 2 is in a soft break when the voltage reaches 1500V, and the leakage current thereof increases slowly, which shows that the HEMT of Example 2 has excellent electrical performance.

According to the above measurement results of the examples and the comparative examples, the units (such as the first unit, the second unit and the third unit) of the superlattice stack layers (such as the first superlattice stack layer, the second superlattice stack layer and the third superlattice stack layer) according to the present disclosure includes the three materials of AlN, AlGaN and GaN stacked in sequence along the vertical direction, which can effectively improve the quality of epitaxy. For example, the FWHM of the GaN crystal can be reduced, and the generation of the crack lines on the surface can be reduced, so that the electrical performance of the semiconductor element can be improved, and the semiconductor device can have an improved characteristic for withstanding voltage.

Compared with the prior art, in the superlattice composite structure according to the present disclosure, with the first superlattice stack layer including the plurality of the first units, the second superlattice stack layer including the plurality of the second units, and each of the first units and each of the second units respectively including the three materials of AlN, AlGaN and GaN stacked in sequence along the vertical direction, it is beneficial to improve the ability for releasing stress and reduce the degree or probability of the generation of crack lines on the surface. Thereby, the semiconductor laminate structure and the semiconductor element including the superlattice composite structure according to the present disclosure can have excellent electrical performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A superlattice composite structure, comprising:
a first superlattice stack layer, comprising a plurality of first units stacked along a vertical direction, wherein each of the first units comprises an aluminium nitride (AlN) layer, an aluminium gallium nitride (AlGaN) layer and a gallium nitride (GaN) layer stacked in sequence along the vertical direction; and
a second superlattice stack layer stacked with the first superlattice stack layer along the vertical direction, wherein the second superlattice stack layer comprises a plurality of second units stacked along the vertical direction, each of the second units comprises another AlN layer, another AlGaN layer and another GaN layer stacked in sequence along the vertical direction, each of the first units has a first unit thickness t1 along the vertical direction, each of the second units has a second unit thickness t2 along the vertical direction, and the following condition is satisfied: t1>t2.

2. The superlattice composite structure of claim 1, further comprising:
a third superlattice stack layer stacked with the first superlattice stack layer and the second superlattice stack layer along the vertical direction, wherein the third superlattice stack layer comprises a plurality of third units stacked along the vertical direction, each of the third units comprises further another AlN layer, further another AlGaN layer and further another GaN layer stacked in sequence along the vertical direction, each of the third units has a third unit thickness t3 along the vertical direction, and the following condition is satisfied: t1>t2>t3.

3. The superlattice composite structure of claim 2, wherein the first unit thickness t1, the second unit thickness t2 and the third unit thickness t3 satisfy the following conditions:
t1>100 Å;
t2>100 Å; and
t3>100 Å.

4. The superlattice composite structure of claim 2, wherein the first superlattice stack layer has a first thickness T1 along the vertical direction, the second superlattice stack layer has a second thickness T2 along the vertical direction, the third superlattice stack layer has a third thickness T3 along the vertical direction, and the following conditions are satisfied:
T1>0.3 μm;
T2>0.3 μm;
T3>0.3 μm; and
$$T 1 > T 2 > T 3.$$

5. The superlattice composite structure of claim 2, wherein the third superlattice stack layer, the second superlattice stack layer and the first superlattice stack layer are stacked in sequence from bottom to top along the vertical direction, or the first superlattice stack layer, the second superlattice stack layer and the third superlattice stack layer are stacked in sequence from bottom to top along the vertical direction.

6. The superlattice composite structure of claim 2, wherein the third superlattice stack layer, the second superlattice stack layer and the first superlattice stack layer are stacked in sequence from bottom to top along the vertical direction, a composition of the AlGaN layer of each of the first units is Al₍₁₋ᵢ₎GaᵢN, a composition of the AlGaN layer of each of the second units is Al₍₁₋ⱼ₎GaⱼN, a composition of the AlGaN layer of each of the third units is Al₍₁₋ₖ₎GaₖN, i is a constant greater than zero and less than 1, j is constant greater than zero and less than 1, k is a constant greater than zero and less than 1, and the following condition is satisfied:
$$i > j > k .$$

7. The superlattice composite structure of claim 2, wherein the AlN layer of each of the first units has a first sub-thickness X1 along the vertical direction, the AlGaN layer of each of the first units has a second sub-thickness Y1 along the vertical direction, the GaN layer of each of the first units has a third sub-thickness Z1 along the vertical direction, the AlN layer of each of the second units has a fourth sub-thickness X2 along the vertical direction, the AlGaN layer of each of the second units has a fifth sub-thickness Y2 along the vertical direction, the GaN layer of each of the second units has a sixth sub-thickness Z2 along the vertical direction, the AlN layer of each of the third units has a seventh sub-thickness X3 along the vertical direction, the AlGaN layer of each of the third units has an eighth sub-thickness Y3 along the vertical direction, the GaN layer of each of the third units has a ninth sub-thickness Z3 along the vertical direction, and the following conditions are satisfied:
$$Y 1 < X 1 < Z 1 ; \\ Y 2 < X 2 < Z 2 ; and \\ Y 3 < X 3 < Z 3.$$

8. The superlattice composite structure of claim 1, wherein the AlN layer of each of the first units has a first sub-thickness X1 along the vertical direction, the AlGaN layer of each of the first units has a second sub-thickness Y1 along the vertical direction, the GaN layer of each of the first units has a third sub-thickness Z1 along the vertical direction, and the second sub-thickness Y1 is between the first sub-thickness X1 and the third sub-thickness Z1.

9. The superlattice composite structure of claim 1, wherein a number of the first units is m, a composition of the AlGaN layer of each of the first units is Al₍₁₋ᵢₐ₎GaᵢₐN, a is an integer from 1 to m, ia is a constant greater than zero and less than 1, in the vertical direction, a composition of the AlGaN layer of the first unit at top most is Al₍₁₋ᵢ₁₎GaᵢN, a composition of the AlGaN layer of the first unit at bottom most is Al₍₁₋ᵢₘ₎GaᵢₘN, and i1 to im decreases gradually from top to bottom along the vertical direction.

10. A semiconductor laminate structure, comprising:
a substrate;
a nucleation layer disposed on the substrate;
the superlattice composite structure of claim 1 disposed on the nucleation layer;
a channel layer disposed on the superlattice composite structure;
a polarized electron generation layer disposed on the channel layer;
a barrier layer disposed on the polarized electron generation layer; and
a cap layer disposed on the barrier layer.
